(19) United States
(12) Patent Application Publication
(10) Pub. No.: US 2023/0068075 A1
(43) Pub. Date: Mar. 2, 2023

(54) CIRCUIT TESTER HAVING AN INTERPOSER TRANSFER BOARD

(71) Applicant: Circuit Check, Inc., Maple Grove, MN (US)

(72) Inventors: William E. CROWTHER, Maple Grove, MN (US); Jason A. SHIELL, Maple Grove, MN (US); Joseph J. PRIHODA, Maple Grove, MN (US)

(21) Appl. No.: 17/823,258

(22) Filed: Aug. 30, 2022

Related U.S. Application Data
(60) Provisional application No. 63/239,662, filed on Sep. 1, 2021.

(51) Int. Cl. G01R 31/28

(52) U.S. Cl. CPC G01R 31/2808

(57) ABSTRACT

A circuit tester includes an interposer transfer board, a mounting plate, at least one sensor plate, and at least one receptacle and probe assembly. The interposer transfer board includes a first surface and a second surface opposite to the first surface, at least one amplifier holder, and at least one input header and at least one output header. The at least one amplifier holder, the at least one input header, and the at least one output header are disposed on the first surface of the interposer transfer board. The at least one receptacle and probe assembly is fixed on the at least one sensor plate. The at least one receptacle and probe assembly passes through and is mounted on the mounting plate. The at least one input header is connected to the at least one receptacle and probe assembly via wires.

### TECHNICAL FIELD

This disclosure relates generally to the field of testing circuit boards. More specifically, the disclosure relates to a circuit tester having an interposer transfer board for testing circuit boards.

### BACKGROUND

Circuit board testers are used for testing a variety of circuit boards or UUT (unit under test which may be something other than a circuit board—the terms will be used interchangeably to refer to all possibilities) or similar devices to assure that the circuit boards operate as intended. In at least one type of circuit board tester, such as Agilent Model No. 3070, Series 3, a separate device, referred to as a fixture, is used to position the circuit board such that a plurality of electrically conductive probes (which are part of, or coupled to, the tester) contact predetermined components or positions of the circuit board. The particular components or positions that are contacted by the test or probes depend on the tests that are desired. When the probes are in contact with the desired locations on the circuit board, electrical signals with predetermined parameters (e.g., predetermined magnitudes or patterns of current, voltage frequency, phase, and the like) are applied by the tester, typically under control of a computer, to certain of the probes. Some or all of the probes are used to measure the performance or response of the circuit board (i.e., to measure electrical parameters at some or all of the probes contacting the circuit board). In this way, it is possible to rapidly perform a number of tests or measurements characterizing the performance of the circuit board while simulating the conditions the circuit board would have, or could have, during actual use. Although it is possible to use these types of tests and testing devices for a variety of possible purposes (such as “spot checking” selected circuit boards at a production facility, testing circuit boards which may be malfunctioning, testing prototype circuit boards as part of a design program, and the like), in at least some applications, circuit board testing is used to provide quality assurance on all or substantially all products of a given type or class which are produced by a company.

### BRIEF SUMMARY

This disclosure relates generally to the field of testing circuit board(s). More specifically, the disclosure relates to a circuit tester having an interposer transfer board for testing circuit board(s).

A circuit tester can have sensor(s) configured to obtain measurements or readings (of e.g., capacitance or the like) through components (e.g., integrated circuits, chips, etc.) that are mounted on the unit under test (UUT). In an application, new technology (e.g., Nano technology) may be applied, which can introduce additional parts to achieve the desired measurements during test. The additional parts may add complexity to the circuit tester design. Embodiments disclosed herein can provide an interposer transfer board (e.g., an amplifier interposer transfer board) to reduce the required part count by removing some parts from the equation. The disclosed interposer transfer board can allow the amplifier to be plugged into a circuit board. Wires can then be wired to such circuit board both on the incoming/input (signal) side and outgoing/output (signal) side. All wiring can be completed by performing standardized wiring procedures.

The disclosed interposer transfer board can be mounted inside a circuit tester. Standardized test assemblies can be installed on desired locations of the unit under test (UUT). These locations can be defined by the customer requirements and/or customer configurations. Wires can be wire-wrapped from the receptacles/probes to the incoming/input (signal) headers on the interposer transfer board. Wires can be then wire-wrapped from the outgoing/output (signal) headers on the interposer transfer board to a multiplexer conditioner card. The amplifiers can be plugged into the interposer transfer board. A cover can be installed to secure the amplifiers into position. The secured position can maintain perpendicularity between the amplifier and the mating connector (e.g., amplifier holder) mounted on the interposer transfer board.

A circuit tester for testing a circuit board or UUT (unit under test) is disclosed. The circuit tester includes an interposer transfer board, a mounting plate, at least one sensor plate, and at least one receptacle and probe assembly. The interposer transfer board includes a first surface and a second surface opposite to the first surface, at least one amplifier holder, and at least one input header and at least one output header. The at least one amplifier holder, the at least one input header, and the at least one output header are disposed on the first surface of the interposer transfer board. The at least one receptacle and probe assembly is fixed on the at least one sensor plate. The at least one receptacle and probe assembly passes through and is mounted on the mounting plate. The at least one input header is connected to the at least one receptacle and probe assembly via wires.

A method for assembling a circuit tester for testing a circuit board or UUT (unit under test) is disclosed. The method includes fixing at least one receptacle and probe assembly on at least one sensor plate, passing the at least one receptacle and probe assembly through a mounting plate and mounting the at least one receptacle and probe assembly on the mounting plate, and wiring at least one input header of an interposer transfer board to the at least one receptacle and probe assembly. The interposer transfer board includes a first surface and a second surface opposite to the first surface, at least one amplifier holder, and the at least one input header and at least one output header. The at least one amplifier holder, the at least one input header, and the at least one output header are disposed on the first surface of the interposer transfer board.

### BRIEF DESCRIPTION OF THE SEVERAL VIEWS OF THE DRAWINGS

References are made to the accompanying drawings that form a part of this disclosure and which illustrate embodiments in which the systems and methods described in this specification can be practiced.

The accompanying drawings illustrate various embodiments of systems, methods, and embodiments of various other aspects of the disclosure. Any person with ordinary skills in the art will appreciate that the illustrated element boundaries (e.g. boxes, groups of boxes, or other shapes) in the figures represent one example of the boundaries. It may be that in some examples one element may be designed as multiple elements or that multiple elements may be designed as one element. In some examples, an element shown as an internal component of one element may be implemented as an external component in another, and vice versa. Furthermore, elements may not be drawn to scale. Non-limiting and non-exhaustive descriptions are described with reference to the following drawings. The components in the figures are not necessarily to scale, emphasis instead being placed upon illustrating principles.

FIG. 1A illustrates a perspective view of a circuit tester having an interposer transfer board, according to an embodiment.

FIG. 1B is the circuit tester of FIG. 1A at a different angle, according to an embodiment.

FIG. 1C illustrates a side view of a circuit tester having an interposer transfer board, according to an embodiment.

FIG. 1D illustrates a top view of a circuit tester having an interposer transfer board, according to an embodiment.

FIG. 1E is an enlarged view of portion of the circuit tester of FIG. 1D, according to an embodiment.

FIGS. 2A-2E illustrate the circuit tester of FIGS. 1A-1E, respectively, with the interposer transfer board having a different configuration, according to some embodiments.

FIGS. 3A-3E illustrate the circuit tester of FIGS. 1A-1E, respectively, with the interposer transfer board having another different configuration, according to some embodiments.

FIG. 4A illustrates a perspective view of an interposer transfer board having a cover, according to an embodiment.

FIG. 4B is the interposer transfer board of FIG. 4A with the cover being removed, according to an embodiment.

FIG. 4C illustrates a top view of the interposer transfer board of FIG. 4B, according to an embodiment.

FIG. 4D illustrates an exploded side view of the interposer transfer board of FIG. 4B, according to an embodiment.

FIG. 4E illustrates an exploded perspective view of the interposer transfer board of FIG. 4B, according to an embodiment.

FIG. 4F is an enlarged view of portion of the interposer transfer board of FIG. 4E, according to an embodiment.

FIGS. 5A-5F illustrate the interposer transfer board of FIGS. 4A-4F, respectively, with a different configuration, according to some embodiments.

FIGS. 6A-6F illustrate the interposer transfer board of FIGS. 4A-4F, respectively, with a different configuration, according to some embodiments.

Like reference numbers represent like parts throughout.

### DETAILED DESCRIPTION

This disclosure relates generally to the field of testing circuit board(s). More specifically, the disclosure relates to a circuit tester having an interposer transfer board for testing circuit board(s).

Some embodiments of the present application are described in detail with reference to the accompanying drawings so that the advantages and features of the present application can be more readily understood by those skilled in the art. The terms “near”, “far”, “top”, “bottom”, “left”, “right” and the like described in the present application are defined according to the typical observation angle of a person skilled in the art and for the convenience of the description. These terms are not limited to specific directions.

One skilled in the art will appreciate that, for this and other processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

Particular embodiments of the present disclosure are described herein with reference to the accompanying drawings; however, it is to be understood that the disclosed embodiments are merely examples of the disclosure, which can be embodied in various forms. Well-known functions or constructions are not described in detail to avoid obscuring the present disclosure in unnecessary detail. Therefore, specific structural and functional details disclosed herein are not to be interpreted as limiting, but merely as a basis for the claims and as a representative basis for teaching one skilled in the art to variously employ the present disclosure in virtually any appropriately detailed structure. In this description, as well as in the drawings, like-referenced numbers represent elements that can perform the same, similar, or equivalent functions.

Additionally, the present disclosure can be described herein in terms of functional block components and various processing steps. It should be appreciated that such functional blocks can be realized by any number of hardware and/or software components configured to perform the specified functions. For example, the present disclosure can employ various processing elements, logic elements, and the like, which can carry out a variety of functions under the control of one or more microprocessors or other control devices.

The scope of the disclosure should be determined by the appended claims and their legal equivalents, rather than by the examples given herein. For example, the steps recited in any method claims can be executed in any order and are not limited to the order presented in the claims. Moreover, no element is essential to the practice of the disclosure unless specifically described herein as “critical” or “essential”.

In an application, new technology (e.g., Nano technology) may be applied, which can create cross-sections issues (e.g., increased cross-sections) for circuit tester design. As a result, additional parts may be needed to use the new technology, which can create added manufacturing processes and operations. In some cases, additional plates can be required for the increase in the cross-section layout. Such changes can increase the cost for each circuit tester (e.g., due to additional manufacturing), increase the time to complete a manufactured circuit tester (e.g., due to additional manufacturing), and increase in weight from the additional plates required to fulfill the new cross-section demands. In addition, the additional parts can also require a near clean room environment for handling and assembly. Furthermore, the additional parts may be manufactured to very tight tolerances and may not be forgiving, causing e.g., frequent receptacle/probe replacement from either being crushed during the delicate installation process or the mounting hole being slightly on the high side of the tolerances and are not retained in the mounting holes.

Circuit board components are being placed closer together on circuit boards and can be high enough above the board surface, and testing devices which measure characteristic of a component (such as an integrated circuit) will stand too tall to have clearance when the cover to the testing enclosure is closed. Such surface testing devices (often referred to as test jets), which are commercially available, such as NanoVtep made by KeySight Technologies are routinely too tall to allow the test enclosure to be closed and test actuation within the enclosure to be performed. See U.S. Pat. Nos. 8,754,665 and 8,847,618 for an example of a test enclosure. A commercial NanoVtep has a sensor plate which contacts the top of the circuit board component, an amplifier, a probe barrel, and pins for transmitting an output to a test circuit. In this disclosure, a structure and method of accommodating the height and spacing clearance problem is proposed.

One aspect of the disclosure is a method for assembling a circuit tester for testing a circuit board or UUT (unit under test), which involves
a. separating an amplifier from a test probe,
b. configuring the test probe to be of height equal to or less than an available test enclosure so it may be closed without engaging and damaging the test probe,
c. locating the amplifier distant from the probe sensor and external of the enclosure on an interposer transfer board,
d. wiring at least one input header of an interposer transfer board to the at least one receptacle and probe assembly,
e. wherein the interposer transfer board includes:
   a first surface and a second surface opposite to the first surface;
   at least one amplifier holder; and
   the at least one input header and at least one output header,
wherein the at least one amplifier holder, the at least one input header, and the at least one output header are disposed on a surface of the interposer transfer board.

Embodiments disclosed herein can provide an interposer transfer board (e.g., an amplifier interposer transfer board) that can be mounted in any suitable location inside a circuit tester due to its compact design and/or footprint. After mounting of the interposer transfer board has been completed, standard test components can be loaded in the top and/or bottom half of a circuit tester. Wires can be added to the receptacles/probes and routed and attached to the incoming/input (signal) header on the interposer transfer board. Wires can also be added to the outgoing/output (signal) header on the interposer transfer board and routed and attached to a multiplexer conditioner board. Each amplifier can be plugged into the corresponding four-position header that is mounted on the interposer transfer board.

Embodiments disclosed herein can provide an interposer transfer board that allows the circuit tester to remove some additional parts required by the Nano technology (e.g., sensor plate(s), receptacle, and/or barrel with spring clip). Those additional parts can create (increased) cross-section issues for the circuit tester and require manufacturing non-standard plates and perform non-standard manufacturing practices, both of which can add time and cost to the projects. The interposer transfer board can remove these additional parts (and thus reducing the added costs) by transferring electrical connection through traces on a printed circuit board (PCB). This also allows removing the “clean room” aspect of the additional parts, which have been recommended to be handled in a clean room environment. The interposer transfer board can be handled like any other PCB and does not require the same clean room standard.

Embodiments disclosed herein can provide an interposer transfer board that can indirectly allow circuit tester to maintain co-planarity between a sensor plate and the component (e.g., integrated circuit, chip, or the like) being tested on the unit under test (UUT). Without the interposer transfer board, the combination of a receptacle and sensor amplifier can be rigid once installed together; variations in components height and co-planarity to the PCB can affect the amplifier with the four-position connector that is mounted on the sensor plate; and uneven pressure can affect the contact continuity.

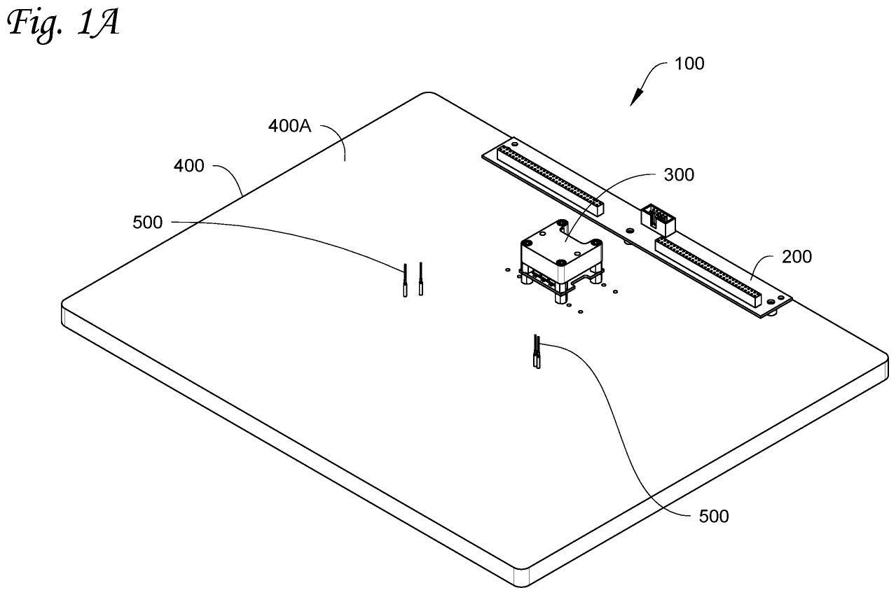

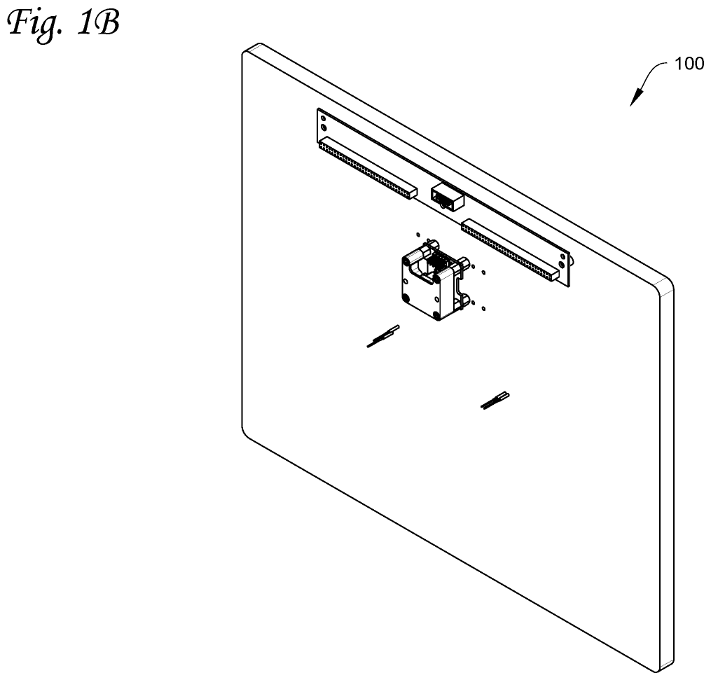

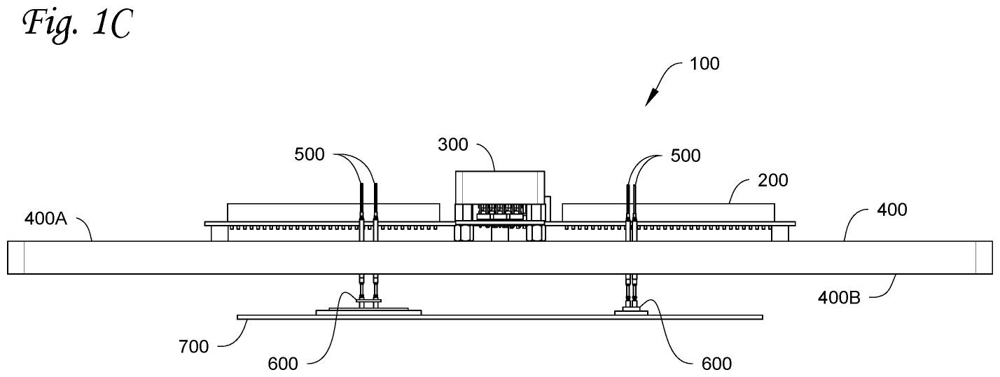

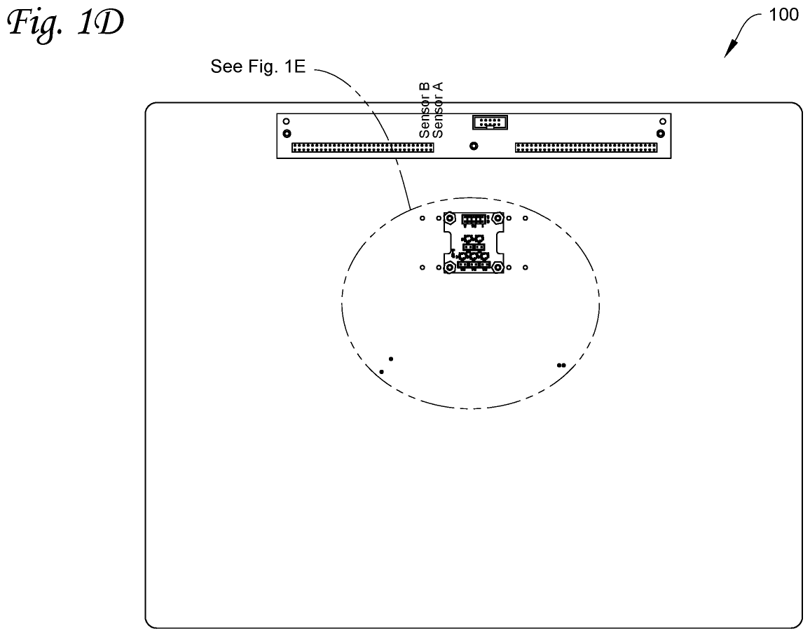

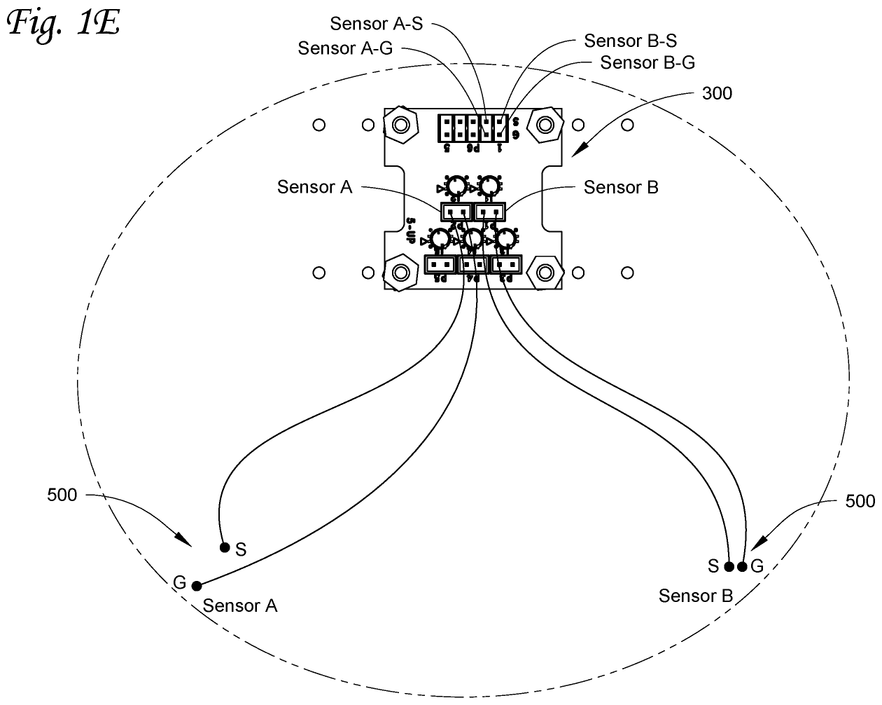

FIG. 1A illustrates a perspective view of a circuit tester 100 having an interposer transfer board 300, according to an embodiment. FIG. 1B is the circuit tester 100 of FIG. 1A at a different angle, according to an embodiment. FIG. 1C illustrates a side view of a circuit tester 100 having an interposer transfer board 300, according to an embodiment. FIG. 1D illustrates a top view of a circuit tester 100 having an interposer transfer board 300, according to an embodiment. FIG. 1E is an enlarged view of portion of the circuit tester 100 of FIG. 1D, according to an embodiment.

As shown in FIGS. 1A-1E, the circuit tester 100 includes a multiplexer card 200, an interposer transfer board 300, a mounting plate or support plate 400, receptacle and probe assemblies 500, and sensor plates 600. A unit under test (UUT) 700 can be removably and rigidly attached to, and/or tested by the circuit tester 100. It will be appreciated that only a few components of the circuit tester 100 are shown in the Figures of this disclosure. The multiplexer (mux) card takes multiple sensor plate signals and divides them into small groups for the test's ASRU card to measure signal strength. It will be appreciated that in an embodiment, the interposer transfer board 300 and/or the components of the interposer transfer board 300 can be plugged directly into the multiplexer (mux) card. Other components of the circuit tester 100 are disclosed in e.g., U.S. Pat. Nos. 8,754,665 and 8,847,618, each of which is incorporated herein by reference in its entirety.

The mounting plate 400 has a first surface 400A, and a second surface 400B opposite to the first surface 400A in a thickness direction of the mounting plate 400. In an embodiment, the multiplexer card 200 and/or the interposer transfer board 300 can be fixed onto the first surface 400A of the mounting plate 400 via any suitable mechanism (e.g., screw(s), fastener(s), welding, or the like).

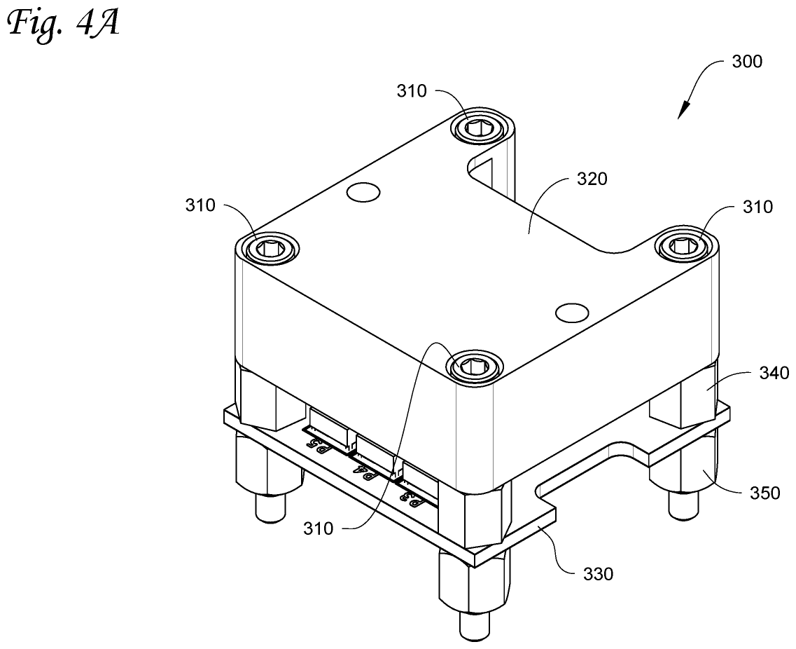

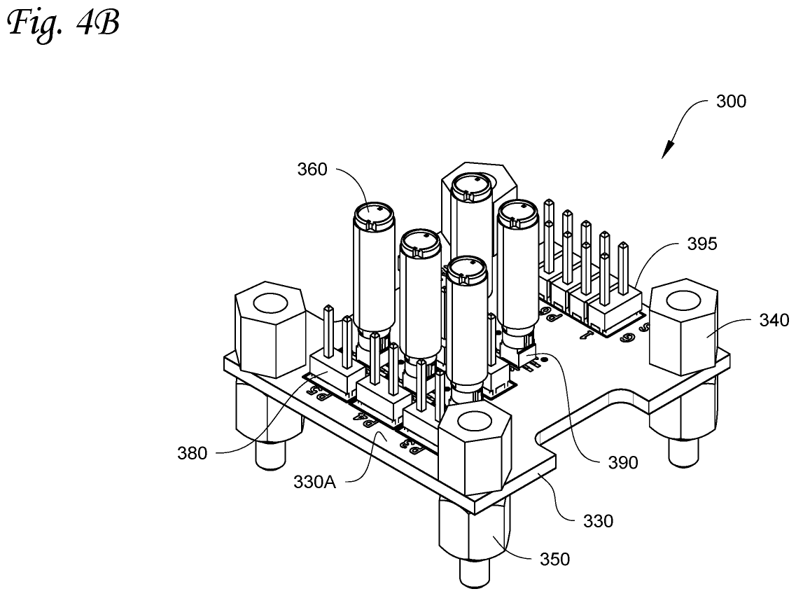

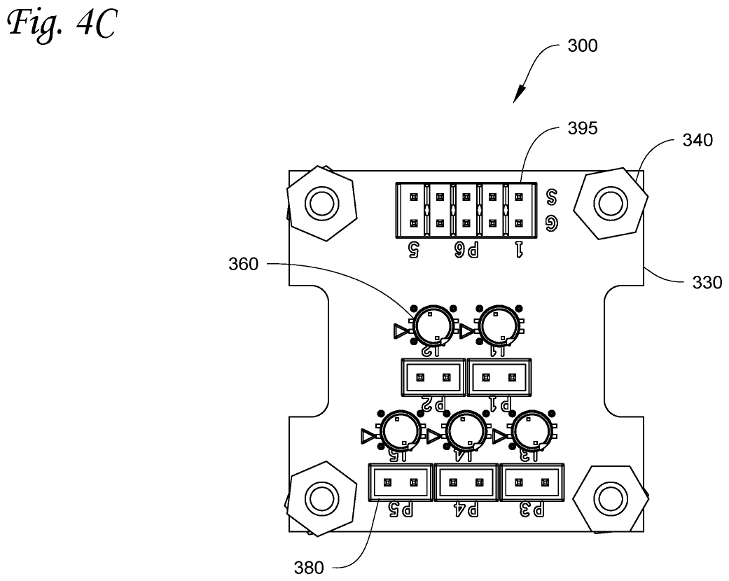

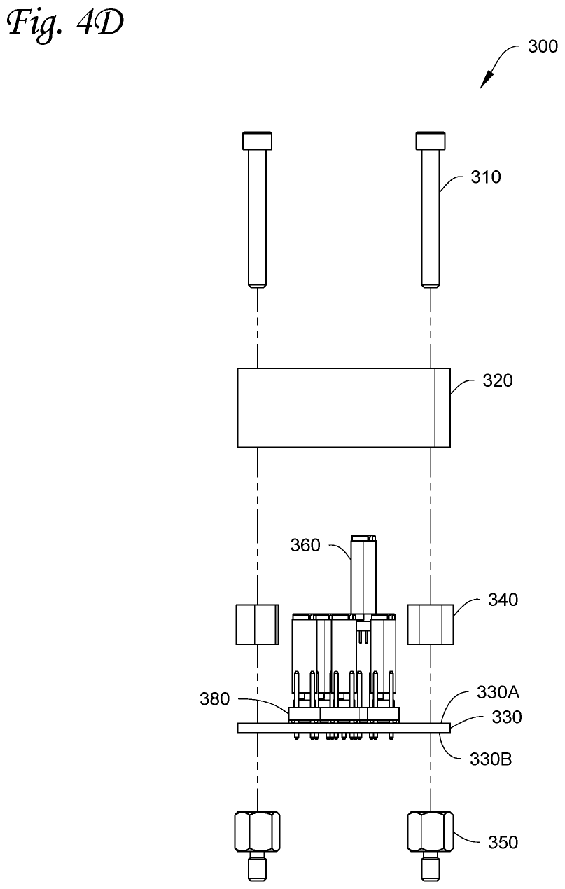

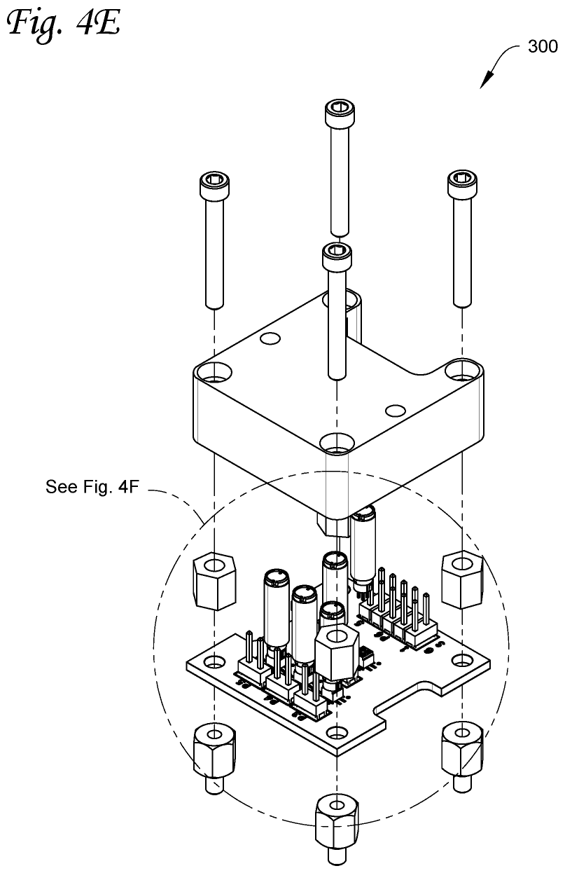

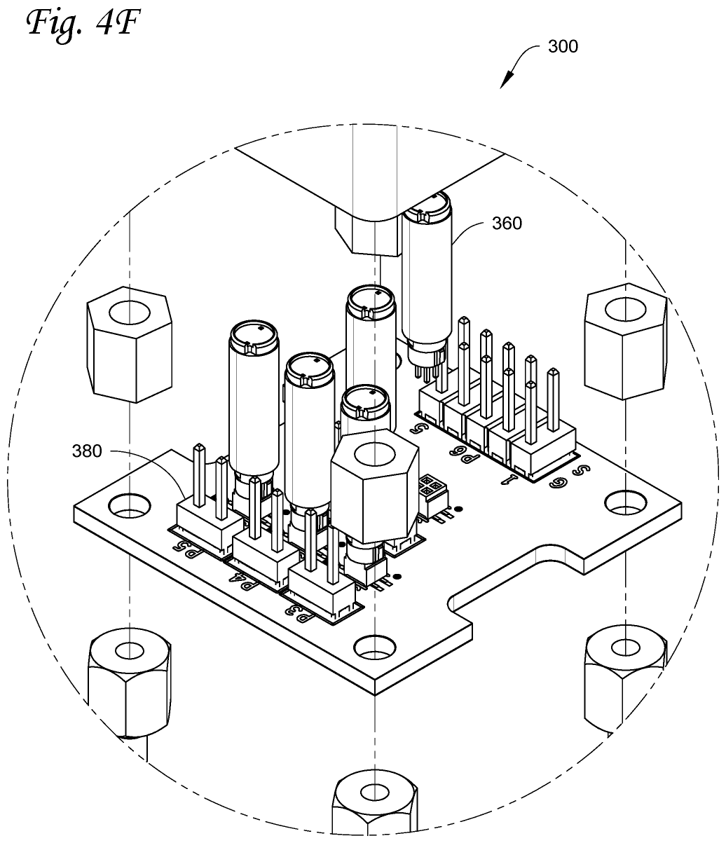

The interposer transfer board 300 includes input headers (see e.g., 380 of FIG. 4B) and output headers (see e.g., 395 of FIG. 4B). The interposer transfer board 300 is described in detail in FIGS. 4A-6F. As shown in FIG. 1E, each input and/or output header of the interposer transfer board 300 can be associated with (e.g., electrically connected to) a sensor (e.g., capacitance sensor, temperature sensor, pressure sensor, or the like), and include two pins S and G. The pin S of the input and/or output header is a sensor signal pin, and the pin G of the input and/or output header is a ground pin.

As shown in FIGS. 1C and 1E, the interposer transfer board 300 includes five input headers, five output headers, and five amplifier holders each receiving an amplifier (to be described in detail in FIGS. 4A-6F), which are disposed on a first surface of the interposer transfer board 300. The circuit tester 100 includes two receptacle and probe assemblies 500, and only two input/output headers are used. It will be appreciated that the number of the input/output headers, the number of the amplifier holders, and/or the number of the receptacle and probe assemblies 500 are not limited to the number specified in FIGS. 1A-1E and can be any suitable number.

In an embodiment, the S and G pins of each input header are connected to the S and G receptacles/probes of each receptacle and probe assembly 500, respectively, via e.g., wires. The S and G pins of each output header are connected to the S and G pins of each header of the multiplexer card 200, respectively, via e.g., wires.

As shown in FIG. 1C, the circuit tester 100 including the mounting plate 400 is disposed on top of the UUT 700. In another embodiment, the circuit tester 100 including the mounting plate 400 can be disposed below the UUT 700.

Each receptacle and probe assembly 500 includes two receptacles/probes S and G (the sensor signal receptacle/probe S and the ground receptacle/probe G). In an embodiment, the receptacle/probe S and/or G can be a spring-loaded probe and/or pushpin. Each receptacle and probe assembly 500 is fixed to a sensor plate 600 via any suitable mechanism (e.g., by welding, or the like).

Each sensor plate 600 includes a sensor (e.g., at the bottom of the sensor plate or at any other suitable location). As shown in FIG. 1C, in testing the UUT 700, the sensor of each sensor plate 600 is attached onto a top of a component or contacts the surface of the component, e.g., an integrated circuit, a chip, or the like) of the UUT 700 to conduct sensor reading(s) (e.g., capacitance) through the component of the UUT 700 (to e.g., ensure that the circuit of the UUT 700 is connected to such component and a trace from a predetermined point A to a predetermined point B is complete). In another embodiment, the sensor of each sensor plate 600 can contact the surface of the component on the bottom surface of UUT 700.

As shown in FIG. 1C, each sensor plate 600 can have a different size (or a same size in another embodiment) to meet different requirements of testing (e.g., corresponding to different or same sizes of the component (being sensed) of the UUT 700). Accordingly, a distance between the S and G receptacles/probes of the corresponding receptacle and probe assembly 500 can be different (or the same in another embodiment).

In an embodiment, each sensor plate 600 can include a dummy electronics board, which can be a connector configured for the S and G receptacles/probes of the corresponding receptacle and probe assembly 500 to plug into (to receive the sensor signal and/or the ground signal, respectively, from the sensor of the sensor plate 600).

As shown in FIG. 1C, each receptacle and probe assembly 500 passes through the mounting plate 400 and is fixed on the mounting plate 400 via any suitable mechanism (e.g., press fit, attachment, or the like).

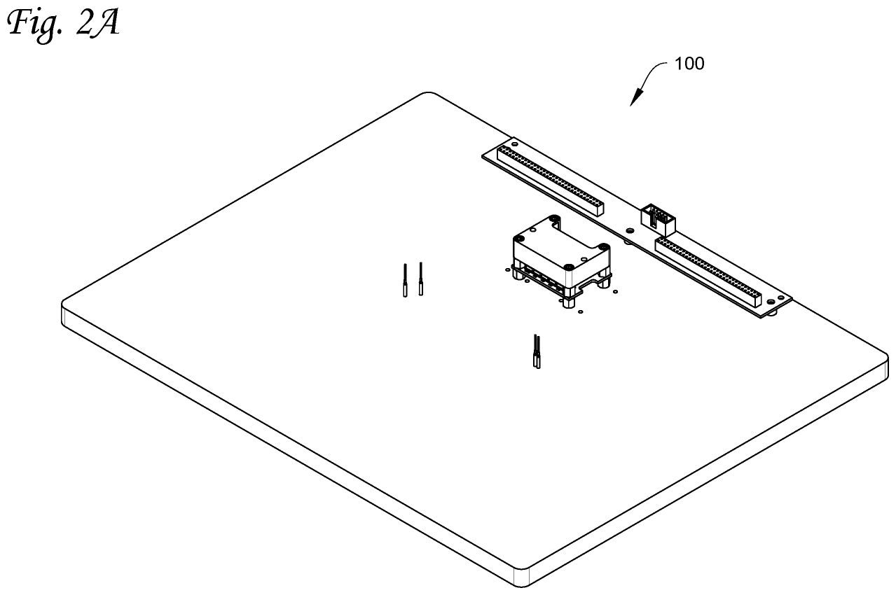

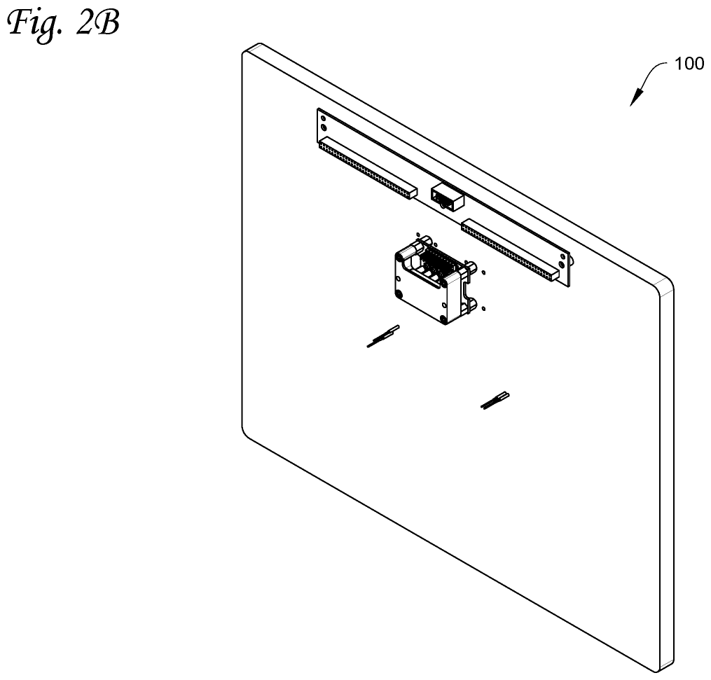

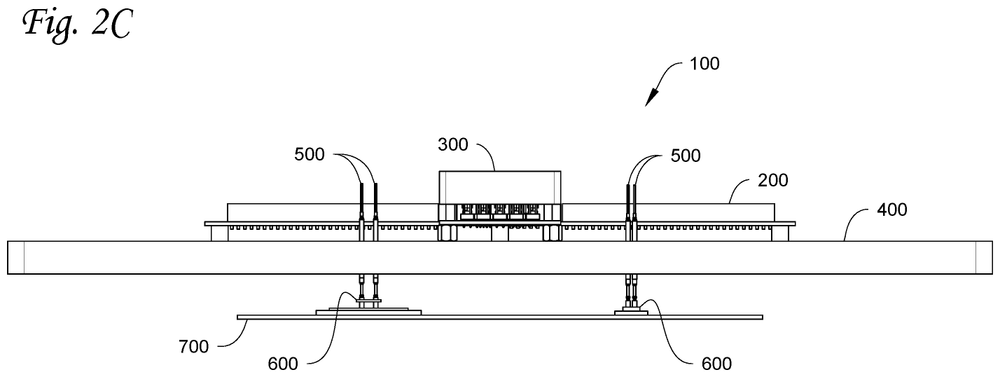

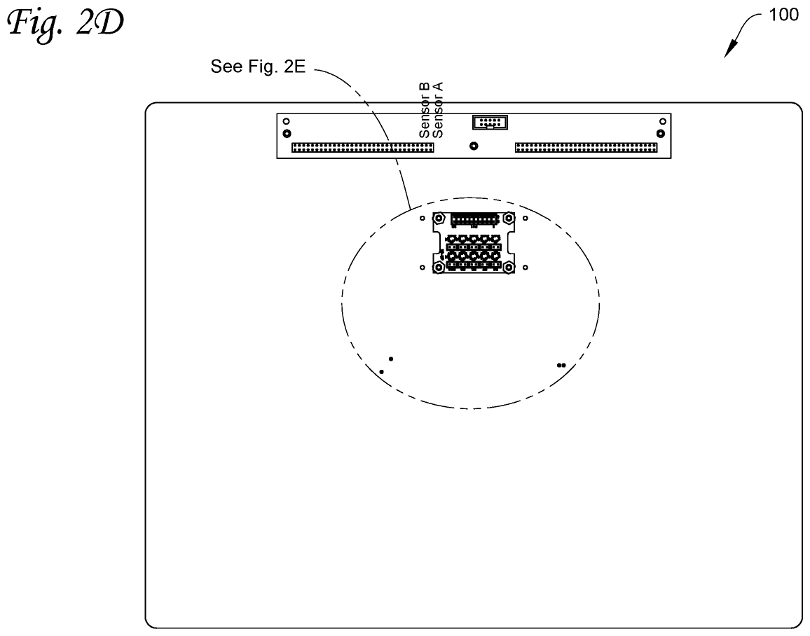

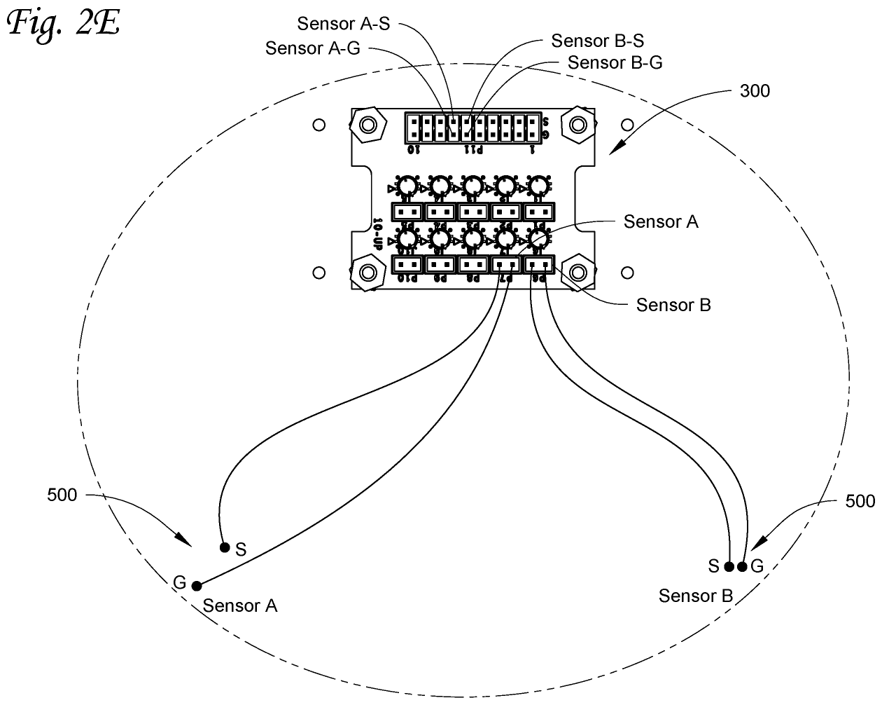

FIGS. 2A-2E illustrate the circuit tester 100 of FIGS. 1A-1E, respectively, with the interposer transfer board 300 having a different configuration, according to some embodiments.

As shown in FIGS. 2A-2E, the interposer transfer board 300 includes ten input headers, ten output headers, and ten amplifier holders each receiving an amplifier (to be described in detail in FIGS. 4A-6F), which are disposed on a first surface of the interposer transfer board 300. The circuit tester 100 includes two receptacle and probe assemblies 500, and only two input/output headers are used. It will be appreciated that the number of the input/output headers, the number of the amplifier holders, and/or the number of the receptacle and probe assemblies 500 are not limited to the number specified in FIGS. 2A-2E and can be any suitable number.

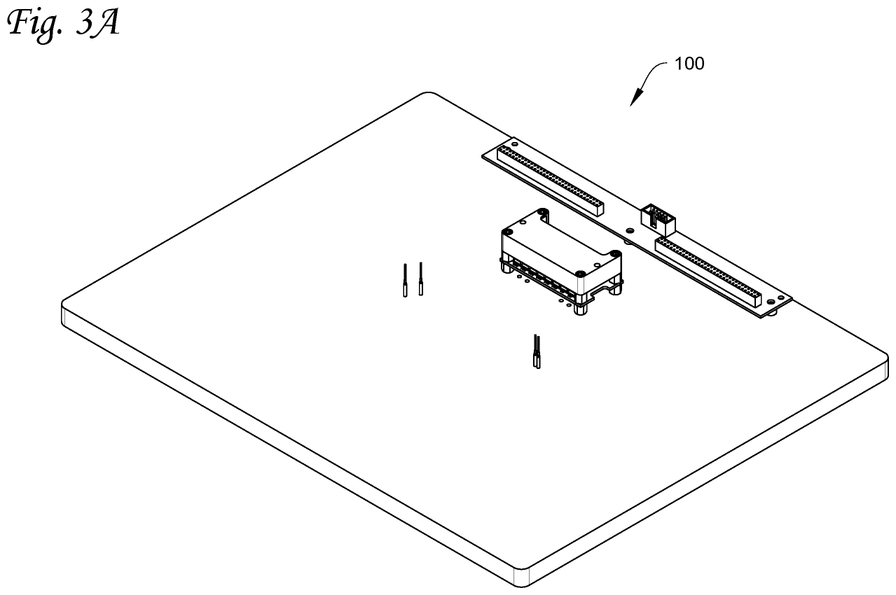

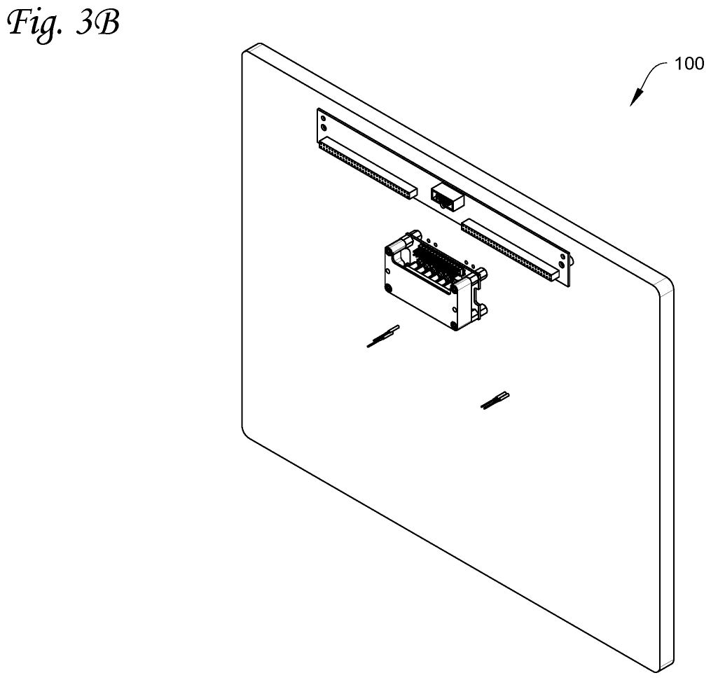

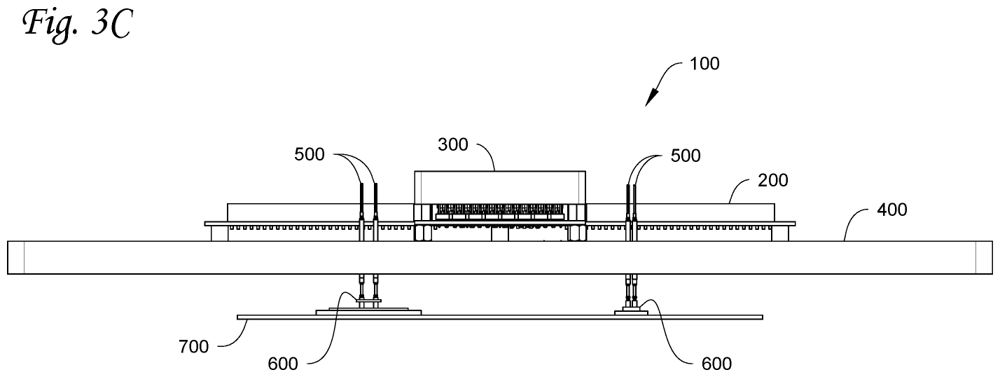

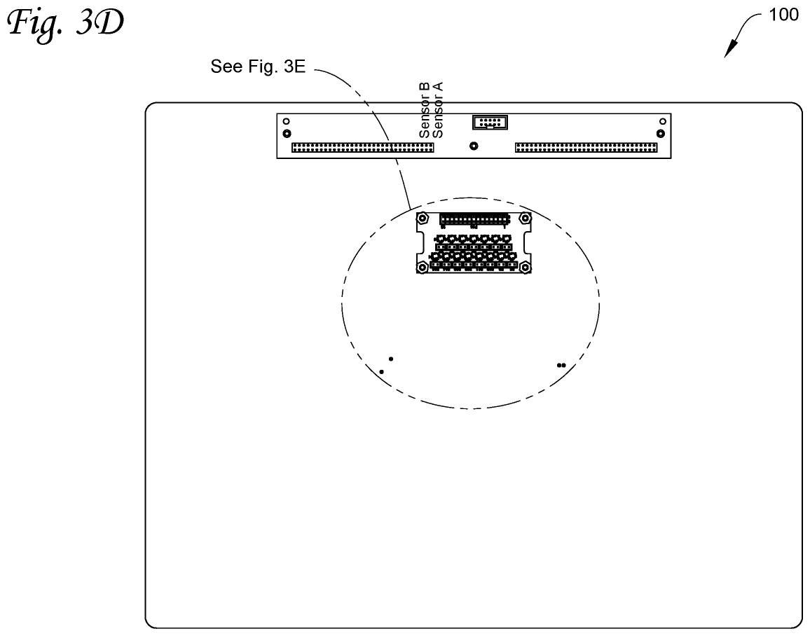

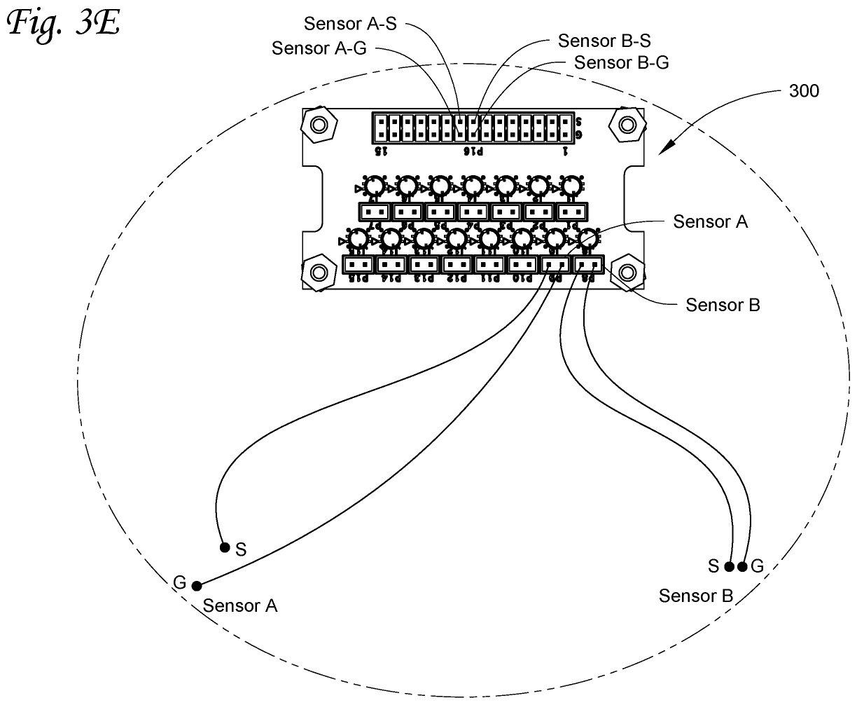

FIGS. 3A-3E illustrate the circuit tester 100 of FIGS. 1A-1E, respectively, with the interposer transfer board 300 having another different configuration, according to some embodiments.

As shown in FIGS. 3A-3E, the interposer transfer board 300 includes fifteen input headers, fifteen output headers, and fifteen amplifier holders each receiving an amplifier (to be described in detail in FIGS. 4A-6F), which are disposed on a first surface of the interposer transfer board 300. The circuit tester 100 includes two receptacle and probe assemblies 500, and only two input/output headers are used. It will be appreciated that the number of the input/output headers, the number of the amplifier holders, and/or the number of the receptacle and probe assemblies 500 are not limited to the number specified in FIGS. 3A-3E and can be any suitable number.

FIG. 4A illustrates a perspective view of an interposer transfer board 300 having a cover 320, according to an embodiment. FIG. 4B is the interposer transfer board 300 of FIG. 4A with the cover being removed, according to an embodiment. FIG. 4C illustrates a top view of the interposer transfer board 300 of FIG. 4B, according to an embodiment. FIG. 4D illustrates an exploded side view of the interposer transfer board 300 of FIG. 4B, according to an embodiment. FIG. 4E illustrates an exploded perspective view of the interposer transfer board 300 of FIG. 4B, according to an embodiment. FIG. 4F is an enlarged view of portion of the interposer transfer board 300 of FIG. 4E, according to an embodiment.

As shown in FIGS. 4A-4F, the interposer transfer board 300 includes a cover 320, fastener(s) 310, standoff(s) 340, standoff(s) 350, a printable circuit board (PCB) 330 having a first surface 330A and a second surface 330B opposite to the first surface 330A in a thickness direction of the PCB 330, input headers 380, amplifier holders 390, and output headers 395.

In an embodiment, the fastener(s) 310 can be screw(s) (e.g., stainless steel screws) or any other suitable fastener(s). The standoff(s) 340 can be nylon standoff(s) or any other suitable standoff(s). The standoff(s) 350 can be stainless steel standoff(s) or any other suitable standoff(s). It will be appreciated that although the number of the fasteners 310 and/or the number of the standoffs (340, 350) are four in FIG. 4E, such number is not limiting and can be any suitable number.

The standoff(s) 340, the input headers 380, the amplifier holders 390, and the output headers 395 are disposed on the first surface 330A of the PCB 330. In an embodiment, the input headers 380, the amplifier holders 390, and the output headers 395 are fixed on the PCB 330 via any suitable mechanism (e.g., welding or the like).

In an embodiment, there can be plug-on headers (optional, not shown) removeably connected to (e.g., being plugged onto) the input headers 380, respectively. Each of the amplifier 360 can removeably connect to (e.g., being plugged into) the amplifier holders 390, respectively. The optional plug-on headers can allow predetermined wire lengths and allow element 300 to be removed for maintenance without remove wires and to change the mux channel if desired.

The cover 320 can be configured to cover the components on the first surface 330A of the PCB 330, and/or to secure the amplifier(s) 360 in position. As shown in FIG. 4A, the cover 320 includes through holes corresponding to the fasteners 310 at the four corners of the cover 320. It will be appreciated that the cover can have any suitable shape other than the shape specified in FIG. 4A. The standoffs 340 can have through holes corresponding to the through holes of the cover 320. The PCB 330 can have through holes (at four corners) corresponding to the through holes of the cover 320. The standoffs 350 can have through holes or recesses corresponding to the through holes of the cover 320. The fasteners 310 can connect the cover 320, the standoffs 340, the PCB 330, and the standoffs 350 via their corresponding through holes (or recesses).

As shown in FIG. 4A, the cover 320 is spaced apart from the PCB 330 by the standoffs 340. The PCB 330 can be spaced apart from the mounting plate (see 400 of FIG. 1C) by the standoffs 350. The cover 320 includes a recess near the output headers 395.

As shown in FIGS. 4B and 4C, the output headers 395 and the input headers 380 are disposed on the PCB 300 opposite to each other in a length direction of the PCB 330. There is a recess on each side of the PCB 330 in a width direction of the PCB board.

In an embodiment, each of the amplifier holders 390 can be a four-position surface mount header that is mounted on the first surface 330A of the PCB 330. Each amplifier 360 can include four pins such that the amplifier 360 can be plugged into the four-position surface mount header 390.

In an embodiment, each of the input headers 380 and/or each of the optional plug-on header can be a two-position header having S (sensor signal) and G (ground) pins. The S pin of the input header 380 or the plug-on header can be connected to the S receptacle/probe of the corresponding receptacle and probe assembly 500 (see e.g., FIG. 1E) via e.g., a sensor signal wire. The G pin of the input header 380 or the plug-on header can be connected to the G receptacle/probe of the corresponding receptacle and probe assembly 500 (see e.g., FIG. 1E) via e.g., a ground wire.

In an embodiment, when the optional plug-on header is plugged onto the corresponding input header 380, the S pin of the plug-on header is electrically connected to the S pin of the corresponding input header 380, and the G pin of the plug-on header is electrically connected to the G pin of the corresponding input header 380.

In an embodiment, each of the output headers 395 can be a two-position header having S (sensor signal) and G (ground) pins. The S pin of the output headers 395 can be connected to the S pin of the corresponding header of the multiplexer card 200 (see e.g., FIGS. 1D and 1E) via e.g., a sensor signal wire. The G pin of the output headers 395 can be connected to the G pin of the corresponding header of the multiplexer card 200 (see e.g., FIGS. 1D and 1E) via e.g., a ground wire.

On the PCB 330, the S pin of the input header 380 can be traced to the S pin of the corresponding output header 395 via the corresponding amplifier holder 390. That is, the sensor signal from the S receptacle/probe of the receptacle and probe assembly 500 can be transmitted to the S pin of the corresponding input header 380 or plug-on header via a wire, then transmitted to the S pin of the corresponding input header 380, and then transmitted to the corresponding amplifier holder 390 (to be amplified by the corresponding amplifier 360), and the amplified sensor signal is then transmitted to the S pin of the corresponding output header 395, and then to the S pin of the corresponding header of the multiplexer card 200, and then to an analyzer (not shown, which is connected to the corresponding header of the multiplexer card 200 via e.g., wires or the like) of the circuit tester 100 for sensor signal analysis.

Similarly, the ground signal from the G receptacle/probe of the receptacle and probe assembly 500 can be transmitted to the G pin of the corresponding input header 380 or plug-on header via a wire, then transmitted to the G pin of the corresponding input header 380, and then transmitted to the corresponding amplifier holder 390 (to be amplified by the corresponding amplifier 360), and the amplified ground signal is then transmitted to the G pin of the corresponding output header 395, and then to the G pin of the corresponding header of the multiplexer card 200, and then to an analyzer (not shown, which is connected to the corresponding header of the multiplexer card 200 via e.g., wires or the like) of the circuit tester 100 for ground signal analysis.

As shown in FIGS. 4A-4F, the interposer transfer board 300 includes five input headers 380 (corresponding to five optional corresponding plug-on headers), five output headers 395, and five amplifier holders 390 each receiving an amplifier 360, which are disposed on the first surface 330A of the interposer transfer board 300. It will be appreciated that the number of the input/output headers, the number of the optional plug-on headers, the number of the amplifier holders, and/or the number of the amplifiers are not limited to the number specified in FIGS. 4A-4F and can be any suitable number.

In an embodiment, the output headers 395 are disposed at a first side of the PCB 330 in the length direction in a side-by-side fashion with S pins being toward the periphery of the first side and G pins being away from the periphery of the first side.

In an embodiment, about half of the input headers 380 are disposed at a second side of the PCB 330 opposite to the first side in the length direction in a side-by-side fashion with S pins and G pins are aligned with each other in the width direction of the PCB 330. About another half of the input headers 380 are disposed around the middle of the PCB 330 in the length direction in a side-by-side fashion with S pins and G pins are aligned with each other in the width direction of the PCB 330. Each amplifier holder 390 is disposed near the corresponding input header 380 toward the first side of the PCB 330.

It will be appreciated that the locations and arrangements of the input headers 380, the output headers 395, and the amplifier holders 390 are not limited to the locations and arrangements specified in FIGS. 4A-4F and can be any suitable locations and arrangements.

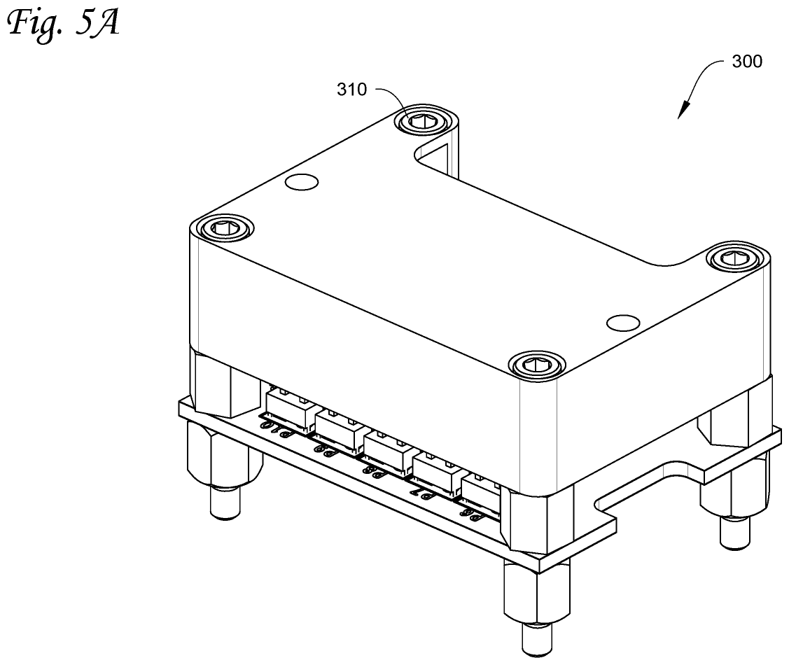

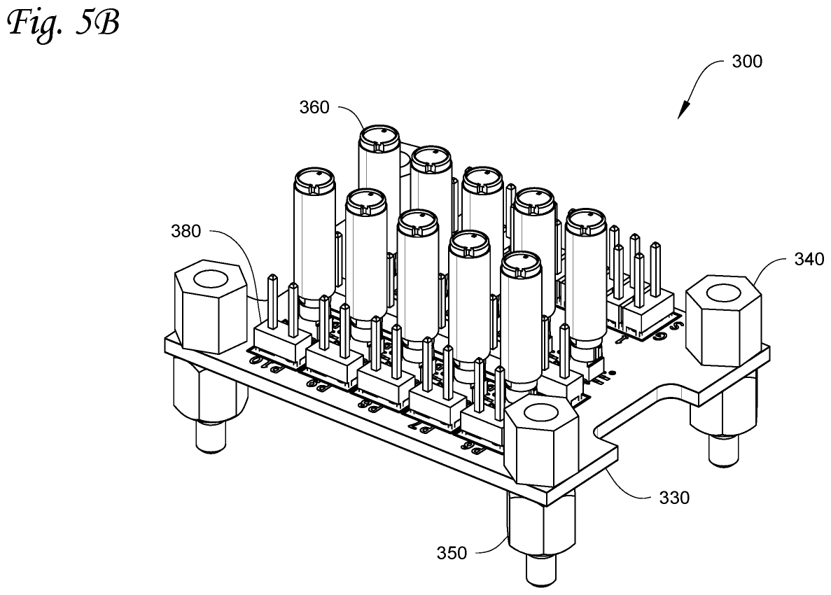

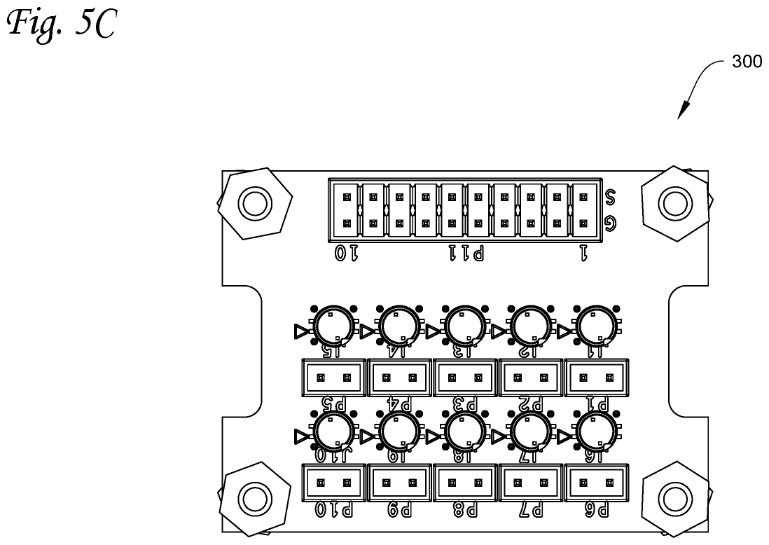

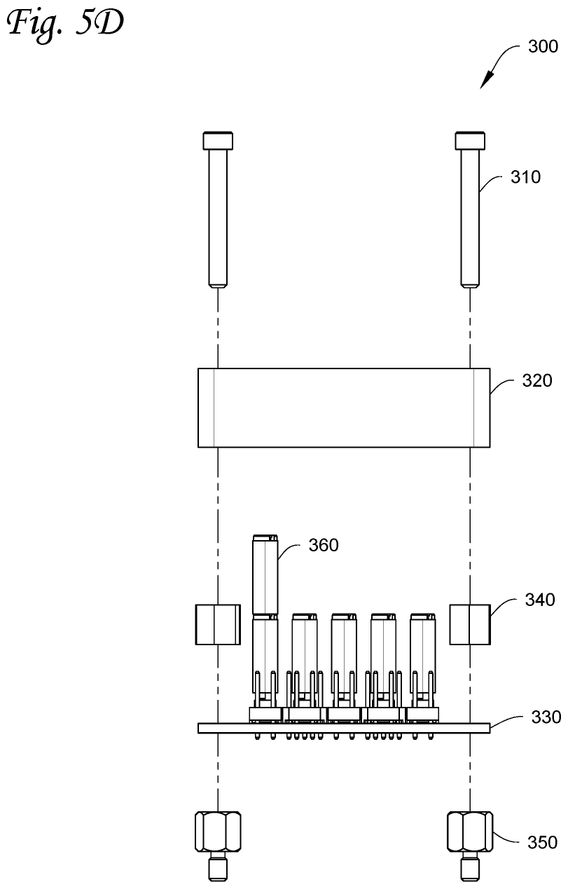

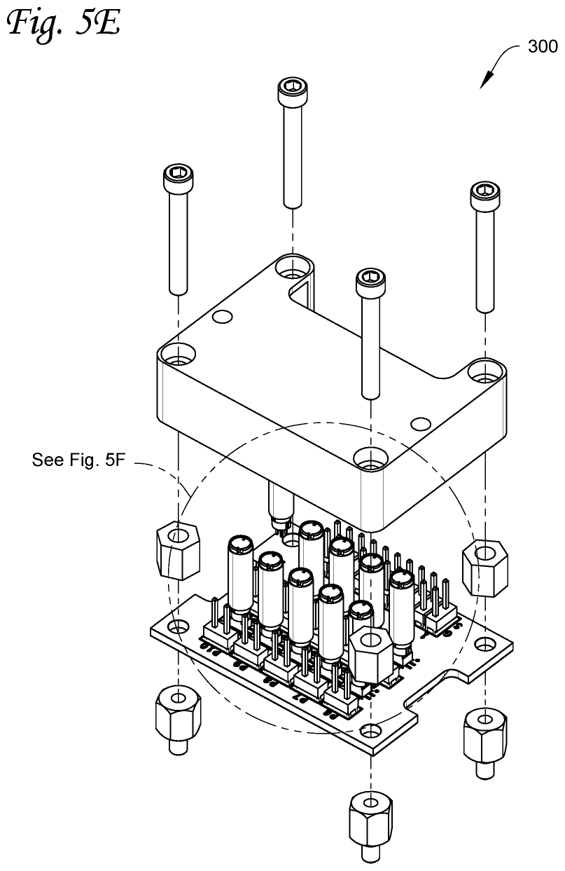

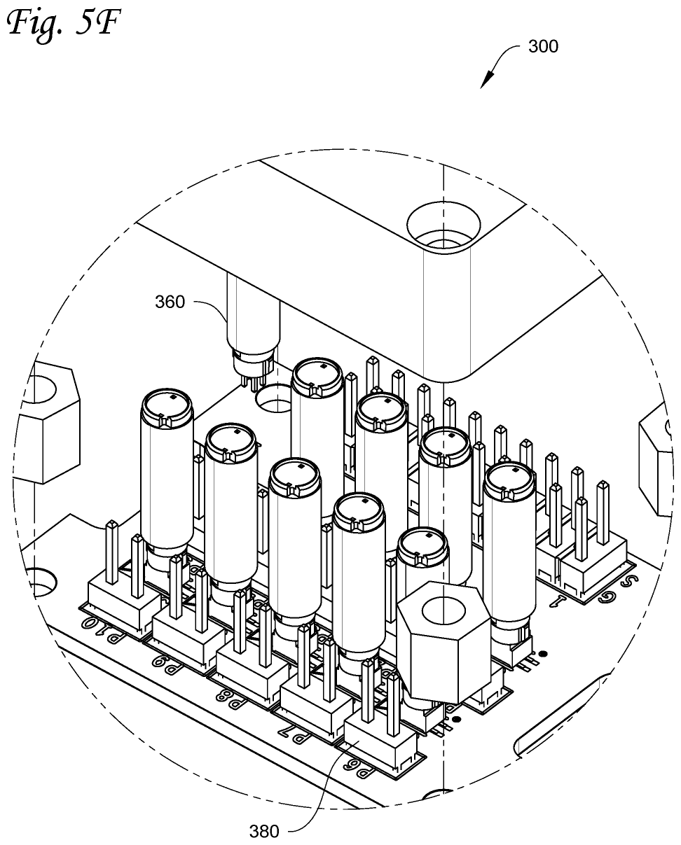

FIGS. 5A-5F illustrate the interposer transfer board 300 of FIGS. 4A-4F, respectively, with a different configuration, according to some embodiments.

As shown in FIGS. 5A-5F, the interposer transfer board 300 includes ten input headers 380 (corresponding to ten optional corresponding plug-on headers), ten output headers 395, and ten amplifier holders 390 each receiving an amplifier 360, which are disposed on the first surface 330A of the interposer transfer board 300. It will be appreciated that the number of the input/output headers, the number of the optional plug-on headers, the number of the amplifier holders, and/or the number of the amplifiers are not limited to the number specified in FIGS. 5A-5F and can be any suitable number.

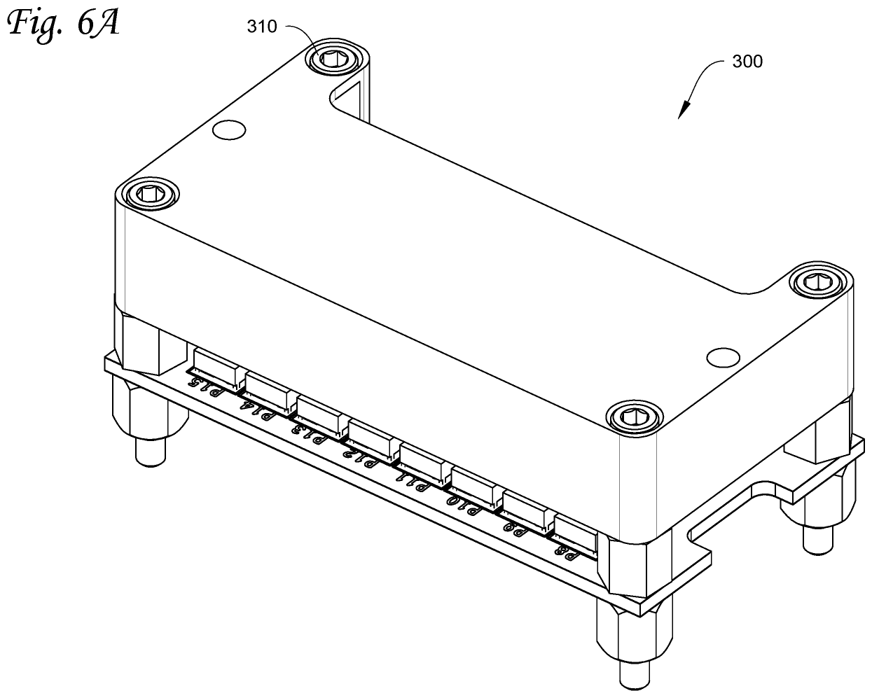

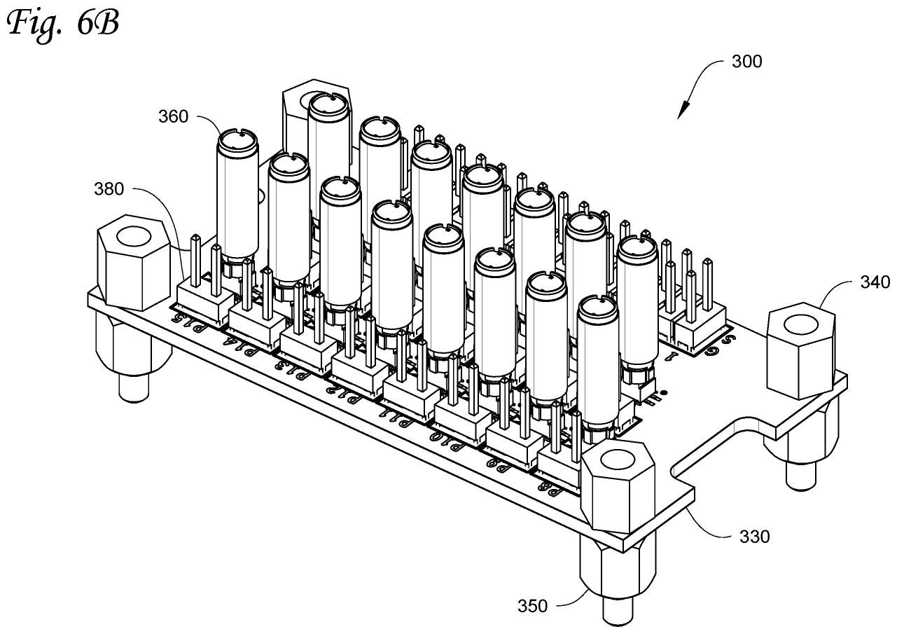

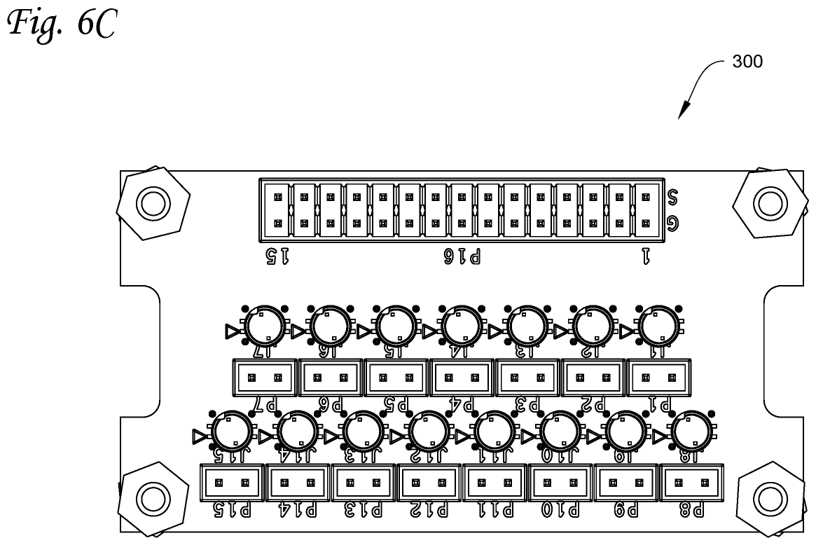

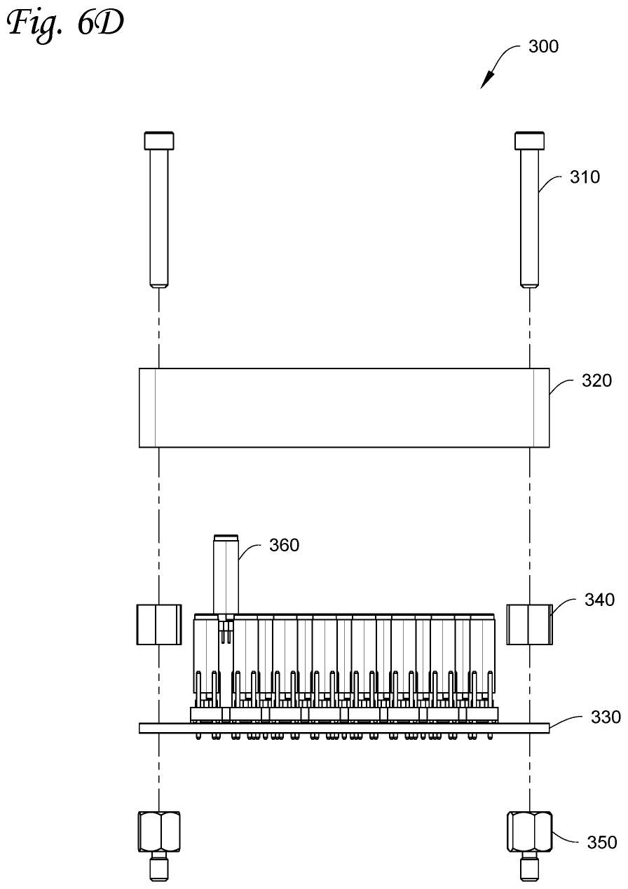

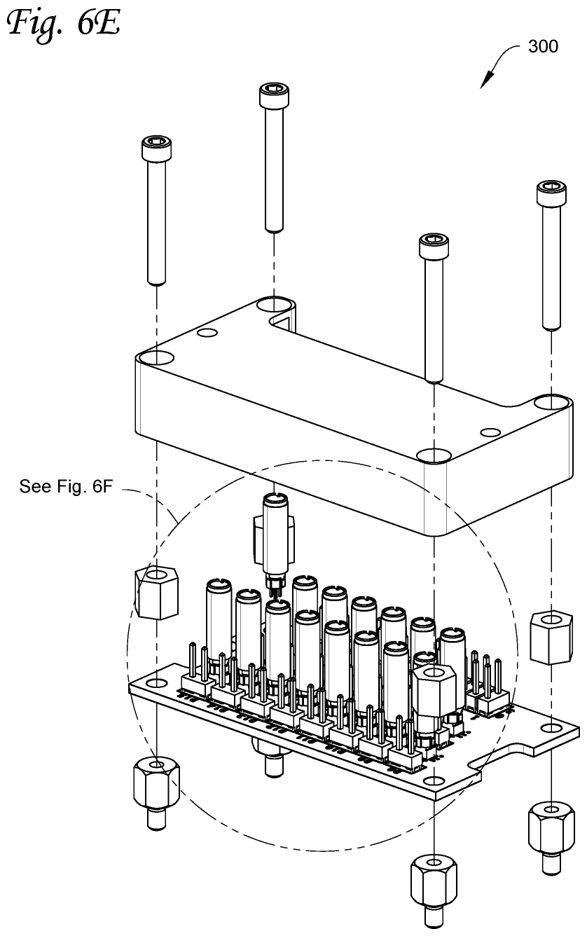

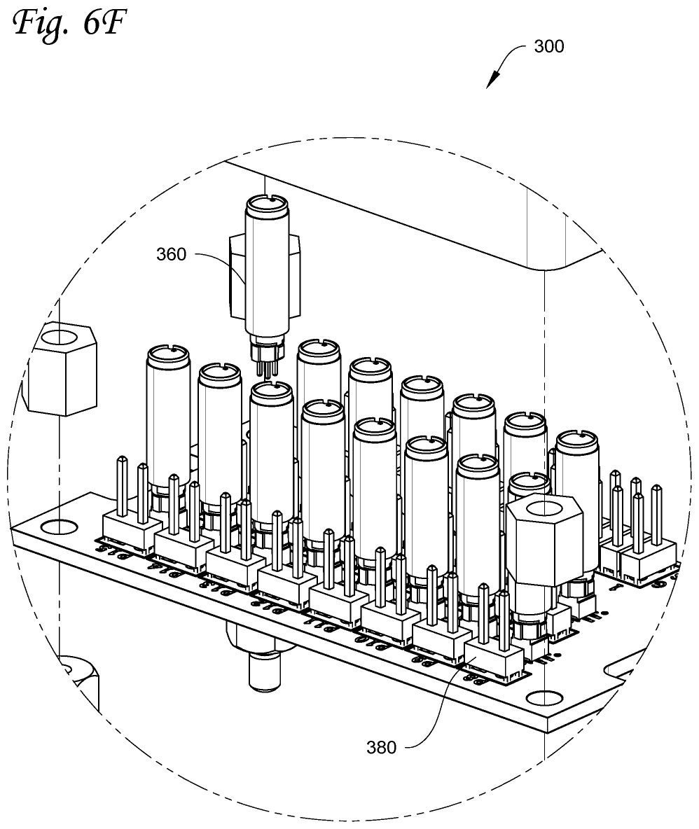

FIGS. 6A-6F illustrate the interposer transfer board 300 of FIGS. 4A-4F, respectively, with a different configuration, according to some embodiments.

As shown in FIGS. 6A-6F, the interposer transfer board 300 includes fifteen input headers 380 (corresponding to fifteen optional corresponding plug-on headers), fifteen output headers 395, and fifteen amplifier holders 390 each receiving an amplifier 360, which are disposed on the first surface 330A of the interposer transfer board 300. It will be appreciated that the number of the input/output headers, the number of the optional plug-on headers, the number of the amplifier holders, and/or the number of the amplifiers are not limited to the number specified in FIGS. 6A-6F and can be any suitable number.

Embodiments disclosed herein can reduce cost (due to removing additional required parts) and manufacturing time, and can reduce inventory and market lead times.

Aspects

It is noted that any one of aspects below can be combined with each other.

Aspect 1. A circuit tester for testing a circuit board or UUT (unit under test), the circuit tester comprising:
an interposer transfer board;
a mounting plate;
at least one sensor plate; and
at least one receptacle and probe assembly,
wherein the interposer transfer board includes:
   a first surface and a second surface opposite to the first surface;
   at least one amplifier holder; and
   at least one input header and at least one output header,
   wherein the at least one amplifier holder, the at least one input header, and the at least one output header are disposed on the first surface of the interposer transfer board,
wherein the at least one receptacle and probe assembly is fixed on the at least one sensor plate,
the at least one receptacle and probe assembly passes through and is mounted on the mounting plate,
the at least one input header is connected to the at least one receptacle and probe assembly via wires.

Aspect 2. The circuit tester of aspect 1, further comprising:
a cover,
wherein the cover is configured to cover the first surface of the interposer transfer board.

Aspect 3. The circuit tester of aspect 1 or aspect 2, wherein the at least one amplifier holder is a four-position surface mount header.

Aspect 4. The circuit tester of any one of aspects 1-3, wherein the interposer transfer board includes five amplifier holders, ten amplifier holders, or fifteen amplifier holders,
each of the amplifier holders is configured to connected to an amplifier.

Aspect 5. The circuit tester of any one of aspects 1-4, wherein the at least one input header is a two-position header.

Aspect 6. The circuit tester of any one of aspects 1-5, wherein the at least one input header is configured to connect to an optional plug-on header.

Aspect 7. The circuit tester of any one of aspects 1-6, wherein the interposer transfer board includes five input headers, ten input headers, or fifteen input headers,
each of the input headers is configured to connected to a receptacle and probe assembly via wires.

Aspect 8. The circuit tester of any one of aspects 1-7, wherein the at least one output header is a two-position header.

Aspect 9. The circuit tester of any one of aspects 1-8, wherein the interposer transfer board includes five output headers, ten output headers, or fifteen output headers.

Aspect 10. The circuit tester of any one of aspects 1-9, wherein the interposer transfer board includes at least one standoff on the first surface and at least one standoff on the second surface.

Aspect 11. A method for assembling a circuit tester for testing a circuit board or UUT (unit under test), the method comprising:
fixing at least one receptacle and probe assembly on at least one sensor plate;
passing the at least one receptacle and probe assembly through a mounting plate and mounting the at least one receptacle and probe assembly on the mounting plate; and
wiring at least one input header of an interposer transfer board to the at least one receptacle and probe assembly,
wherein the interposer transfer board includes:
   a first surface and a second surface opposite to the first surface;
   at least one amplifier holder; and
   the at least one input header and at least one output header,
   wherein the at least one amplifier holder, the at least one input header, and the at least one output header are disposed on the first surface of the interposer transfer board.

Aspect 12. The method of aspect 11, further comprising:
covering the first surface of the interposer transfer board with a cover.

Aspect 13. The method of aspect 11 or aspect 12, wherein the at least one amplifier holder is a four-position surface mount header.

Aspect 14. The method of any one of aspects 11-13, wherein the interposer transfer board includes five amplifier holders, ten amplifier holders, or fifteen amplifier holders,
the method further comprising:
   connecting each of the amplifier holders to an amplifier.

Aspect 15. The method of aspects 11-14, wherein the at least one input header is a two-position header.

Aspect 16. The method of aspects 11-15, further comprising:
connecting the at least one input header to an optional plug-on header.

Aspect 17. The method of aspects 11-16, wherein the interposer transfer board includes five input headers, ten input headers, or fifteen input headers,
the method further comprising:
   connecting each of the input headers to a receptacle and probe assembly via wires.

Aspect 18. The method of aspects 11-17, wherein the at least one output header is a two-position header.

Aspect 19. The method of aspects 11-18, wherein the interposer transfer board includes five output headers, ten output headers, or fifteen output headers.

Aspect 20. The method of aspects 11-19, wherein the interposer transfer board includes at least one standoff on the first surface and at least one standoff on the second surface.

The examples disclosed in this application are to be considered in all respects as illustrative and not limitative. The scope of the invention is indicated by the appended claims rather than by the foregoing description; and all changes which come within the meaning and range of equivalency of the claims are intended to be embraced therein.

The terminology used in this specification is intended to describe particular embodiments and is not intended to be limiting. The terms “a,” “an,” and “the” include the plural forms as well, unless clearly indicated otherwise. The terms “comprises” and/or “comprising,” when used in this specification, specify the presence of the stated features, integers, steps, operations, elements, and/or components, but do not preclude the presence or addition of one or more other features, integers, steps, operations, elements, and/or components.

With regard to the preceding description, it is to be understood that changes may be made in detail, especially in matters of the construction materials employed and the shape, size, and arrangement of parts without departing from the scope of the present disclosure. This specification and the embodiments described are exemplary only, with the true scope and spirit of the disclosure being indicated by the claims that follow.

What is claimed is:

1. A circuit tester for testing a circuit board or UUT (unit under test), the circuit tester comprising:
an interposer transfer board;
a mounting plate;
at least one sensor plate; and
at least one receptacle and probe assembly,
wherein the interposer transfer board includes:
a first surface and a second surface opposite to the first surface;
at least one amplifier holder; and
at least one input header and at least one output header,
wherein the at least one amplifier holder, the at least one input header, and the at least one output header are disposed on the first surface of the interposer transfer board,
wherein the at least one receptacle and probe assembly is fixed on the at least one sensor plate,
the at least one receptacle and probe assembly passes through and is mounted on the mounting plate,
the at least one input header is connected to the at least one receptacle and probe assembly via wires.

2. The circuit tester of claim 1, further comprising:
a cover,
wherein the cover is configured to cover the first surface of the interposer transfer board.

3. The circuit tester of claim 1, wherein the at least one amplifier holder is a four-position surface mount header.

4. The circuit tester of claim 1, wherein the interposer transfer board includes five amplifier holders, ten amplifier holders, or fifteen amplifier holders,
each of the amplifier holders is configured to connected to an amplifier.

5. The circuit tester of claim 1, wherein the at least one input header is a two-position header.

6. The circuit tester of claim 1, wherein the interposer transfer board includes five input headers, ten input headers, or fifteen input headers,
each of the input headers is configured to connected to a receptacle and probe assembly via wires.

7. The circuit tester of claim 1, wherein the at least one output header is a two-position header.

8. The circuit tester of claim 1, wherein the interposer transfer board includes five output headers, ten output headers, or fifteen output headers.

9. The circuit tester of claim 1, wherein the interposer transfer board includes at least one standoff on the first surface and at least one standoff on the second surface.

10. A method for assembling a circuit tester for testing a circuit board or UUT (unit under test), the method comprising:
fixing at least one receptacle and probe assembly on at least one sensor plate;
passing the at least one receptacle and probe assembly through a mounting plate and mounting the at least one receptacle and probe assembly on the mounting plate; and
wiring at least one input header of an interposer transfer board to the at least one receptacle and probe assembly,
wherein the interposer transfer board includes:
a first surface and a second surface opposite to the first surface;
at least one amplifier holder; and
the at least one input header and at least one output header,
wherein the at least one amplifier holder, the at least one input header, and the at least one output header are disposed on the first surface of the interposer transfer board.

11. The method of claim 10, further comprising:
covering the first surface of the interposer transfer board with a cover.

12. The method of claim 10, wherein the at least one amplifier holder is a four-position surface mount header.

13. The method of claim 10, wherein the interposer transfer board includes five amplifier holders, ten amplifier holders, or fifteen amplifier holders,
the method further comprising:
connecting each of the amplifier holders to an amplifier.

14. The method of claim 10, wherein the at least one input header is a two-position header.

15. The method of claim 10, wherein the interposer transfer board includes five input headers, ten input headers, or fifteen input headers,
the method further comprising:
connecting each of the input headers to a receptacle and probe assembly via wires.

16. The method of claim 10, wherein the at least one output header is a two-position header.

17. The method of claim 10, wherein the interposer transfer board includes five output headers, ten output headers, or fifteen output headers.

18. The method of claim 10, wherein the interposer transfer board includes at least one standoff on the first surface and at least one standoff on the second surface.
